(19) United States
(12) Patent Application Publication
(10) Pub. No.: US 2011/0017285 A1
(43) Pub. Date: Jan. 27, 2011

(54) Solar Cell with Textured Coverglass

(75) Inventors: Arthur Cornfeld, Sandia Park, NM (US); Tansen Varghese, Albuquerque, NM (US)

Correspondence Address: EMCORE CORPORATION, 1600 EUBANK BLVD, S.E., ALBUQUERQUE, NM, 87123, US

(73) Assignee: Emcore Solar Power, Inc., Albuquerque, NM (US)

(21) Appl. No.: 12/507,996

(22) Filed: Jul. 23, 2009

(51) Int. Cl. H01L 31/00; H01L 31/18

(52) U.S. Cl. 136/255; 438/69; 257/E31.127

(57) ABSTRACT

A solar cell including a semiconductor body including at least one photoactive junction, and a textured layer or coverglass having a textured surface disposed over the top surface of the semiconductor body. The textured layer may be between 200 and 1800 nm in thickness, and may have a graded index of refraction.

### BACKGROUND OF THE INVENTION

1. Field of the Invention

The present invention relates to the field of solar cell semiconductor devices, and particularly to the structure and composition of the coverglass typically employed over the semiconductor body.

2. Description of the Related Art.

Photovoltaic cells, also called solar cells, are one of the most important new energy sources that have become available in the past several years. Considerable effort has gone into solar cell development. As a result, solar cells are currently being used in a number of commercial and consumer-oriented applications. While significant progress has been made in this area, the requirement for solar cells to meet the needs of more sophisticated applications has not kept pace with demand. Applications such as satellites used in data communications have dramatically increased the demand for solar cells with improved power and energy conversion characteristics.

Solar power from photovoltaic cells has been predominantly provided by silicon semiconductor technology. In the past several years, however, high-volume manufacturing of III-V compound semiconductor multijunction solar cells for space applications has accelerated the development of such technology not only for use in space but also for terrestrial solar power applications. Compared to silicon, III-V compound semiconductor multijunction devices have greater energy conversion efficiencies and generally more radiation resistance, although they tend to be more complex to manufacture. Typical commercial III-V compound semiconductor multijunction solar cells have energy efficiencies that exceed 27% under one sun, air mass 0 (AM0), illumination, whereas even the most efficient silicon technologies generally reach only about 18% efficiency under comparable conditions. Under high solar concentration (e.g., 500×), commercially available III-V compound semiconductor multijunction solar cells in terrestrial applications (at AM1.5D) have energy efficiencies that exceed 37%. The higher conversion efficiency of III-V compound semiconductor solar cells compared to silicon solar cells is in part based on the ability to achieve spectral splitting of the incident radiation through the use of a plurality of photovoltaic regions with different band gap energies, and accumulating the current from each of the regions.

In satellite and other space related applications, the size, mass and cost of a satellite power system are dependent on the power and energy conversion efficiency of the solar cells used. Putting it another way, the size of the payload and the availability of on-board services are proportional to the amount of power provided. Thus, as payloads become more sophisticated, the power-to-weight ratio of a solar cell becomes increasingly more important, and there is increasing interest in lighter weight, “thin film” type solar cells having both high efficiency and low mass.

Typical III-V compound semiconductor solar cells are fabricated on a semiconductor wafer in vertical, multijunction structures. The individual solar cells or wafers are then disposed in horizontal arrays, with the individual solar cells connected together in an electrical series circuit. The shape and structure of an array, as well as the number of cells it contains, are determined in part by the desired output voltage and current.

In some implementations of a solar cell array, the top surface of the solar cell may be bonded with a ceria containing flat coverglass, such as described in U.S. Pat. No. 6,156,967. Although such a standard coverglass may be adequate for many applications, the use of solar cells in space presents additional challenges for which improved optical performance is sought.

### SUMMARY OF THE INVENTION

### 1. Objects of the Invention

It is an object of the present invention to provide an improved coverglass for a solar cell.

It is an object of the invention to provide an improved solar cell structure for space applications.

It is still another object of the invention to provide a method of manufacturing a solar cell having a textured layer or coverglass.

Some implementations or embodiments of the invention may achieve fewer than all of the foregoing objects.

Additional objects, advantages, and novel features of the present invention will become apparent to those skilled in the art from this disclosure, including the following detailed description as well as by practice of the invention. While the invention is described below with reference to preferred embodiments, it should be understood that the invention is not limited thereto. Those of ordinary skill in the art having access to the teachings herein will recognize additional applications, modifications and embodiments in other fields, which are within the scope of the invention as disclosed and claimed herein and with respect to which the invention could be of utility.

### 2. Features of the Invention

Briefly, and the general terms, the present invention provides a solar cell comprising: a semiconductor body including at least one photoactive junction; and a textured surface layer disposed over the top surface of the semiconductor body.

The present invention further provides a method of manufacturing a solar cell by providing a substrate; depositing on the substrate a sequence of layers of semiconductor material forming a solar cell; and mounting a protective glass including a textured surface over the solar cell.

Some implementations or embodiments of the invention may incorporate or implement achieve fewer of the aspects and features noted in the foregoing summaries.

### BRIEF DESCRIPTION OF THE DRAWINGS

These and other features and advantages of this invention will be better and more fully appreciated by reference to the following detailed description when considered in conjunction with the accompanying drawings, wherein:

FIG. 1 is an enlarged cross-sectional view of the solar cell as known in the prior art at the end of the process steps of forming the layers of the solar cell on a first substrate;

FIG. 2 is an enlarged cross-sectional view of the solar cell according to the present invention in a first embodiment;

FIG. 3 is a cross-sectional view of the solar cell structure according to the present invention in a second embodiment;

FIG. 4 is a perspective view of a portion of the surface of the coverglass structure according to the present invention in a moth-eye embodiment; and

FIG. 5 is a perspective view of a portion of the surface of the coverglass structure according to the present invention in another moth-eye embodiment.

### DESCRIPTION OF THE PREFERRED EMBODIMENT

Details of the present invention will now be described including exemplary aspects and embodiments thereof. Referring to the drawings and the following description, like reference numbers are used to identify like or functionally similar elements, and are intended to illustrate major features of exemplary embodiments in a highly simplified diagrammatic manner. Moreover, the drawings are not intended to depict every feature of the actual embodiment nor the relative dimensions of the depicted elements, and are not drawn to scale.

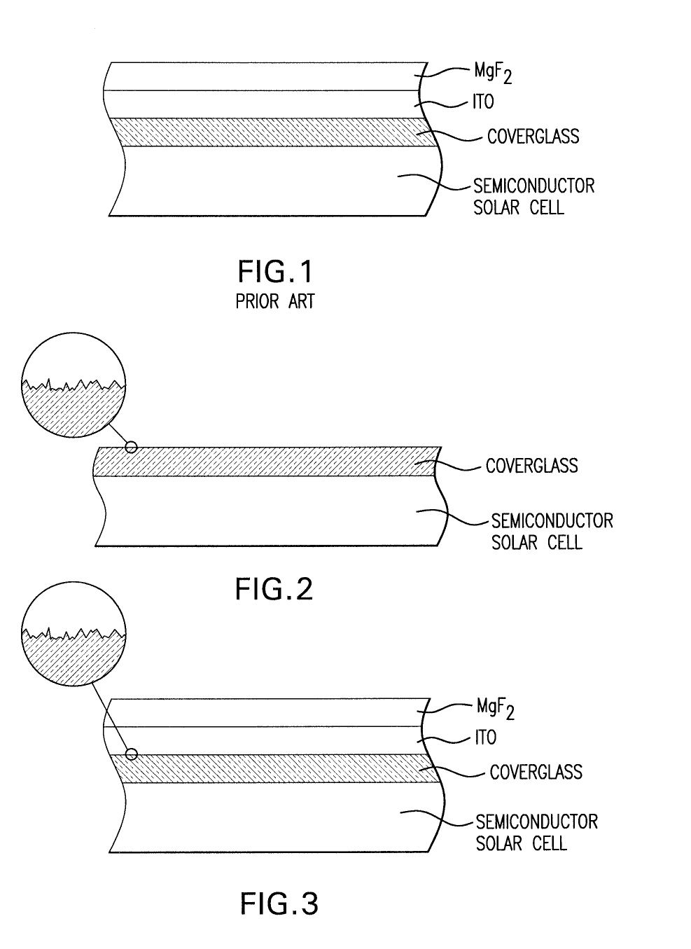

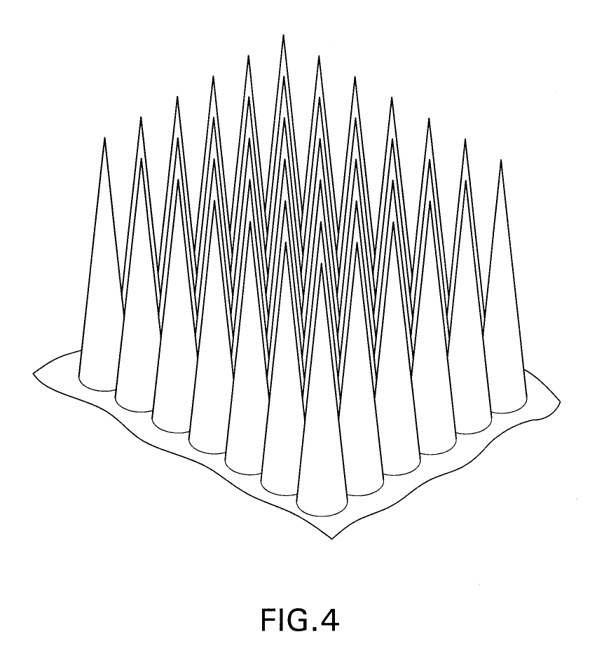

FIG. 1 depicts a cross-sectional view of a solar cell according to the prior art, and in particular illustrating the coverglass and the layers forming a protective coating disposed above the solar cell semiconductor body. The design of a typical semiconductor structure of a triple junction III-V compound semiconductor solar cell is more particularly described in U.S. Pat. No. 6,680,432, herein incorporated by reference. One type of triple junction structure in an embodiment of the present invention is the structure consisting of a germanium bottom cell, a gallium arsenide (GaAs) middle cell, and an indium gallium phosphide (InGaP) top cell.

The current standard practice for implementing a coverglass is to use a ceria doped glass material, typically about 4 mils in thickness, with optional layers of MgF₂ as an anti-reflective coating (ARC), and indium-tin oxide (ITO) as a conductive coating, over the coverglass. The ITO helps to alleviate electrostatic discharge (ESD) on solar cells with coverglass.

Current high efficiency multijunction solar cells typically use dual layer TiOx/Al₂O₃ coatings on the front to act as an anti-reflection coating (ARC). TiOx has an index of refraction of about 2.3, and A1₂O₃ has an index of refraction of about 1.7. By depositing appropriate layers on the front or top surface of the GaInP₂/GaAs/Ge semiconductor body multijunction device, the Al₂O₃/TiOx structure reduces the reflection of incoming sunlight to much lower levels.

As shown in FIG. 2, one embodiment of the present invention is to use a textured or rough surface, preferably from 200 nm to 1800 nm in thickness, on the top surface of the solar cell coverglass. The textured surface may be an irregular and random pattern, or may be a geometrical pattern such as a pattern of regular polygons of the same dimension, or polygons of different dimension. In some embodiments, the pattern may be similar to a “moth-eye” , and may have a thickness from 200 to 1800 nm. In some embodiments, a refractive index gradient may also be employed, in combination with the texturing, in the patterned region. The gradient may be implemented in discrete steps, or continuously, by different techniques as discussed below

The textured surface is effective for improving the performance of the solar cell since by increasing the number of reflections experienced by an incoming light ray reduces energy loss, and also increases the optical path length through the solar cell, since the multiple incoming beams will enter the cell at oblique angles to the surface of the cell, and will traverse an oblique path through the cell.

Certain patterns such as the “moth-eye” reduce reflection by introducing a refractive index gradient in place of refractive index steps. The moth-eye texture has a periodicity of less than the minimum wavelength of light in the coverglass, which means diffraction effects are reduced, and the moth-eye layer can be treated as a graded refractive index layer, as the amount of material reduces from the bulk coverglass to the tips of the moth-eye pyramids. Other methods of introducing a refractive index gradient would be by sol-gel coatings of graded porosity, etching or leaching out material to create graded porosity in a film, or depositing films at various successive angles (normal to oblique angles), to create nanopillars with different levels of porosity incorporated in-between. The porosity should be arranged to increase in the direction from the bulk coverglass to the surface. In such embodiment, the porosity should preferably be of a dimension less than the minimum wavelength of light, i.e. around 200 nm.

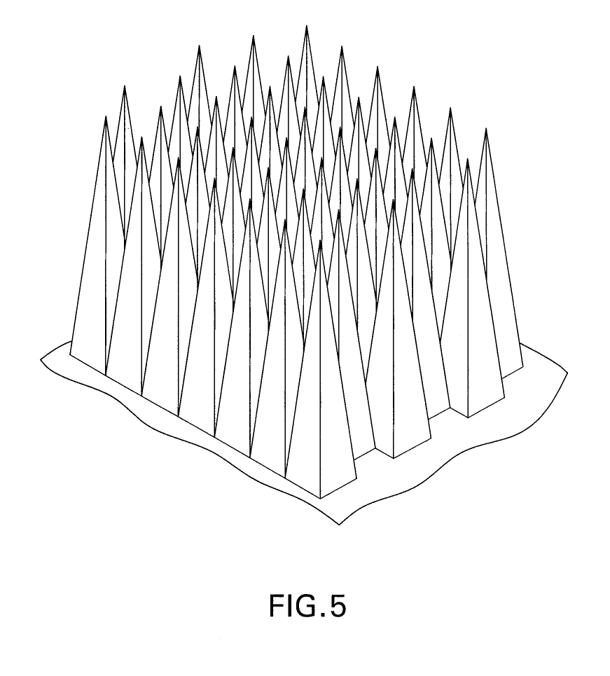

FIG. 4 is a perspective view of a portion of the surface of the coverglass structure according to the present invention illustrating an embodiment using a moth-eye pattern. In one embodiment, the moth-eye pattern is composed of cone-like structures patterned over the surface at a height in a range from 200 to over 500 nm from the planar surface of the coverglass. The peaks of the cones are approximately 200 nm apart, and in a preferred embodiment the height of the cone over the surface level is 1800 nm.

FIG. 5 is a perspective view of a portion of the surface of the coverglass structure according to the present invention illustrating another embodiment using a moth-eye pattern. In this embodiment, the moth-eye pattern is composed of pyramid-like structures patterned over the surface, with alternate rows being staggered. The structures preferably have a height in a range from 200 to over 500 nm from the planar surface of the coverglass. The peaks of the pyramids are approximately 200 nm apart, and in a preferred embodiment the height of the pyramid over the surface level is 1800 nm.

Although the illustrated moth-eye embodiments are depicted as either cones or pyramids, and either uniformly arrayed, or in staggered arrays, other geometric structures and staggering arrangements may be implemented in further embodiments.

Although the preferred embodiment of the semiconductor solar cell utilizes the III-V compound semiconductor materials described above, the embodiment is only illustrative, and it should be noted that the multijunction solar cell structure could be formed by any suitable combination of group III to V elements listed in the periodic table subject to lattice constant and band gap requirements, wherein the group III includes boron (B), aluminum (Al), gallium (Ga), indium (In), and thallium (T). The group IV includes carbon (C), silicon (Si), germanium (Ge), and tin (Sn). The group V includes nitrogen (N), phosphorous (P), arsenic (As), antimony (Sb), and bismuth (Bi).

Although this aspect of the invention has been described in certain specific embodiments, many additional modifications and variations would be apparent to those skilled in the art. This aspect of the present invention is, therefore, considered in all respects to be illustrative and not restrictive. The scope of this aspect of the invention is indicated by the relevant appended claims, and all changes that come within the meaning and range of equivalents thereof are intended to be embraced therein.

It will be understood that each of the elements described above, or two or more together, also may find a useful application in other types of constructions differing from the types described above.

While the aspect of the invention has been illustrated and described as embodied in a solar cell using III-V compound semiconductors, it is not intended to be limited to the details shown, since various modifications and structural changes may be made without departing in any way from the spirit of the present invention.

Without further analysis, the foregoing will so fully reveal the gist of the present invention that others can, by applying current knowledge, readily adapt it for various applications without omitting features that, from the standpoint of prior art, fairly constitute essential characteristics of the generic or specific aspects of this invention and therefore, such adaptations should and are intended to be comprehended within the meaning and range of equivalence of the following claims.

1. A solar cell comprising:
a semiconductor body including at least one photoactive junction; and
a textured ceria doped glass disposed over the top surface of said semiconductor body.

2. The solar cell as defined in claim 1 wherein the top surface of the coverglass is textured.

3. The solar cell as defined in claim 1 wherein the coverglass is approximately 4 mils in thickness and with portion of the glass which is textured is about 200 to 1800 nm in thickness.

4. The solar cell as defined in claim 1 wherein the top surface of the coverglass is textured so that the incoming light is bent through a plurality of angles so that it is incident upon the surface of the semiconductor body at oblique angles.

5. The solar cell as defined in claim 1 wherein the top surface of the coverglass is textured in a moth-eye pattern.

6. The solar cell as defined in claim 1 wherein the top surface of the coverglass is textured in a pattern of polygons of substantially equal dimension.

7. The solar cell as defined in claim 1 wherein the top surface of the coverglass is textured in a pattern of polygons of different dimension.

8. The solar cell as defined in claim 1 wherein the top surface of the coverglass is composed of a material having a gradient in the index of refraction from the surface.

9. The solar cell as defined in claim 8 wherein the gradient in the index of refraction is a plurality of steps.

10. The solar cell as defined in claim 1 further comprising an antireflection coating deposited over the top surface of the coverglass.

11. The solar cell as defined in claim 1 wherein the semiconductor body comprises group III-V compound semiconductor elements.

12. The solar cell as defined in claim 1 wherein the semiconductor body comprises a multijunction solar cell.

13. A solar cell as defined in claim 1, wherein the semiconductor body includes a substrate selected from the group consisting of germanium or GaAs.

14. A multijunction solar cell as defined in claim 12, wherein the multijunction solar cell includes a first solar subcell is composed of germanium.

15. A multijunction solar cell as defined in claim 12, wherein the multijunction solar cell includes a second solar subcell composed of GaAs.

16. A multijunction solar cell as defined in claim 12, wherein the multijunction solar cell includes a top solar subcell composed of GaInP.

17. A solar cell as defined in claim 1, wherein the coverglass is adhered to the semiconductor body by a substantially transparent adhesive, the adhesive remaining substantially transparent when exposed to an AM0 space environment

18. A method of manufacturing a solar cell comprising:
providing a semiconductor body including at least one photoactive junction; and
attaching a light refracting coverglass over the top surface of said semiconductor body.

19. A method as defined in claim 18, further comprising texturing the top surface of the coverglass to a depth of between 200 and 1800 nm.

20. A method as defined in claim 18, further comprising forming a gradient in the index of refraction of top surface of the coverglass at a depth of between 200 and 1800 nm.
